(19) United States
(12) Patent Application Publication
(10) Pub. No.: US 2026/0105231 A1
(43) Pub. Date: Apr. 16, 2026

(54) ADAPTIVE SEMI-FORMAL BUG HUNTING

(71) Applicant: International Business Machines Corporation, Armonk, NY (US)

(72) Inventors: Raj Kumar Gajavelly, Bangalore (IN); Jason Raymond Baumgartner, Austin, TX (US); Robert Lowell Kanzelman, Rochester, MN (US); Bradley Donald Bingham, Austin, TX (US)

(73) Assignee: International Business Machines Corporation, Armonk, NY (US)

(21) Appl. No.: 18/915,279

(22) Filed: Oct. 14, 2024

(51) Int. Cl. G06F 30/3323

(52) U.S. Cl. CPC G06F 30/3323

(57) ABSTRACT

A computer-implemented method of rarity-guided semi-formal verification includes processing circuitry of a data processing system performing semi-formal verification (SFV) of a logic design utilizing a combination of bounded model checking (BMC) and simulation. The processing circuitry guides progress of the simulation in the SFV based on rarity of simulated sub-states of register partitions of the logic design. Guiding the simulation in the SFV includes discounting, in computation of a rarity score, one or more register partitions nearing saturation. Based on the SFV, the processing circuitry identifies a satisfied verification property.

### BACKGROUND OF THE INVENTION

The present invention relates in general to integrated circuit design, and more specifically, to semi-formal verification of an integrated circuit design.

Functional verification is critical element in the development of today's complex integrated circuit designs. Simulation is prevalently used to identify design flaws. However, insufficient coverage, i.e. the inability of simulation to identify every design flaw and provide correctness proofs, limits the cost-effectiveness and adequacy of simulation. In contrast, formal verification (FV) is exhaustive, and thus can provide orders of magnitude higher coverage than simulation. FV therefore can identify even extremely improbable corner-case bugs, and also provide correctness proofs. FV has thus flourished as an industry-essential technology to complement the coverage achievable with simulation and sometimes replace it. However, the applicability of FV is limited due to scalability challenges, which render FV prohibitively slow or inconclusive on very large scale designs.

Semi-formal verification (SFV) is a promising technology that leverages symbolic algorithms of FV to achieve significantly higher coverage on larger, more-complex designs than those to which FV can be applied. SFV, however, lacks full exhaustiveness and thus the ability to provide correctness proofs. Existing SFV approaches typically use a resource-bounded symbolic algorithm called bounded model checking (BMC) to exhaustively check for property violations within a fixed number of timesteps from a starting state. SFV often is implemented in conjunction with simulation that explores a subset of design states from which BMC is applied, thereby allowing the identification of deeper bugs than possible using BMC alone due to its scalability limitations. The success of SFV thus depends heavily upon the quality of the set of states from which BMC is performed. If successive BMC runs overlap in the set of states they verify, processing resources can be wasted, and the probability of selecting a starting state near a property violation is reduced.

While SFC is very powerful at finding deep corner-case bugs on large integrated circuit designs, SFV is subject to multiple historical limitations that limit its effectiveness. First, the rarity computation utilized to identify qualitatively diverse design states is slower than simulation itself, limiting coverage. Second, random simulation tends the repeatedly revisit the same design states, wasting resources. For example, in random simulation of a design with a reset input, every other simulation pattern on average will reset the design if not biased to prevent reset in some way. Third, symbolic algorithms such as BMC are prone to exhausting machine memory as the search progresses more deeply—a condition known in the art as “memout.” If memout occurs, SFV terminates, leaving unsolved properties. Arbitrary resource bounding to prevent memout may also hurt effectiveness, for example, by precluding adequately deep search on very deep designs. Fourth, concurrently checking a large number of properties risks limiting BMC depth. Thus, for example, a single difficult-for-BMC property will limit BMC depth achieved before resource limits are exhausted for easier properties. Fifth, limiting BMC to a selection among multiple starting states historically risks hurting BMC scalability and thus depth achieved, risking coverage degradation. Sixth, robust SFV engines typically require a large number of parameters and heuristics to yield best coverage on different designs and properties. Finding the best settings is difficult and generally wastes processing resources, for example, by running large portfolios of differently configured SFV engines in parallel.

### SUMMARY OF THE INVENTION

The present application presents SFV techniques having improved coverage, bug and verification coverage closure, and efficiency, allowing more complex bugs to be identified with less computational resource than possible in the prior art.

According to one or more embodiments, a computer-implemented technique of rarity-guided semi-formal verification includes processing circuitry of a data processing system performing semi-formal verification (SFV) of a logic design utilizing a combination of bounded model checking (BMC) and simulation. The processing circuitry guides progress of the simulation in the SFV based on rarity of simulated sub-states of register partitions of the logic design. Guiding the simulation in the SFV includes discounting, in computation of a rarity score, one or more register partitions nearing saturation. Based on the SFV, the processing circuitry identifies a satisfied verification property.

The disclosed techniques can be realized as methods, systems, and/or program products.

### BRIEF DESCRIPTION OF THE DRAWINGS

FIG. 1 is a high-level block diagram of an exemplary data processing environment in accordance with one or more embodiments;

FIG. 2 is a high-level logical flowchart of an integrated circuit design, verification, and fabrication process in accordance with one or more embodiments;

FIG. 3 is a graphical representation of a semi-formal verification (SFV) process that employs bit-parallel simulation and bounded model checking (BMC) in accordance with the prior art;

FIG. 4 a high-level logical flowchart of an exemplary process for prioritizing state rarity during SFV in accordance with one or more embodiments;

FIG. 5 is a high-level logical flowchart of an exemplary process for prioritizing partitions during SFV in accordance with one or more embodiments;

FIG. 6 is a high-level logical flowchart of an exemplary process for dynamically adjusting input value biases during SFV in accordance with one or more embodiments;

FIG. 7 is a high-level logical flowchart of an exemplary process for applying localization during SFV in accordance with one or more embodiments;

FIG. 8 is a high-level logical flowchart of an exemplary process for performing BMC from multiple starting states with reduced scalability degradation in accordance with one or more embodiments;

FIG. 9 is a high-level logical flowchart of an exemplary process for avoiding memory exhaustion (“memout”) during SFV in accordance with one or more embodiments; and

FIGS. 10-11 together form a high-level logical flowchart of an exemplary process for adaptive search to improve coverage and scalability of SFV in accordance with one or more embodiments.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

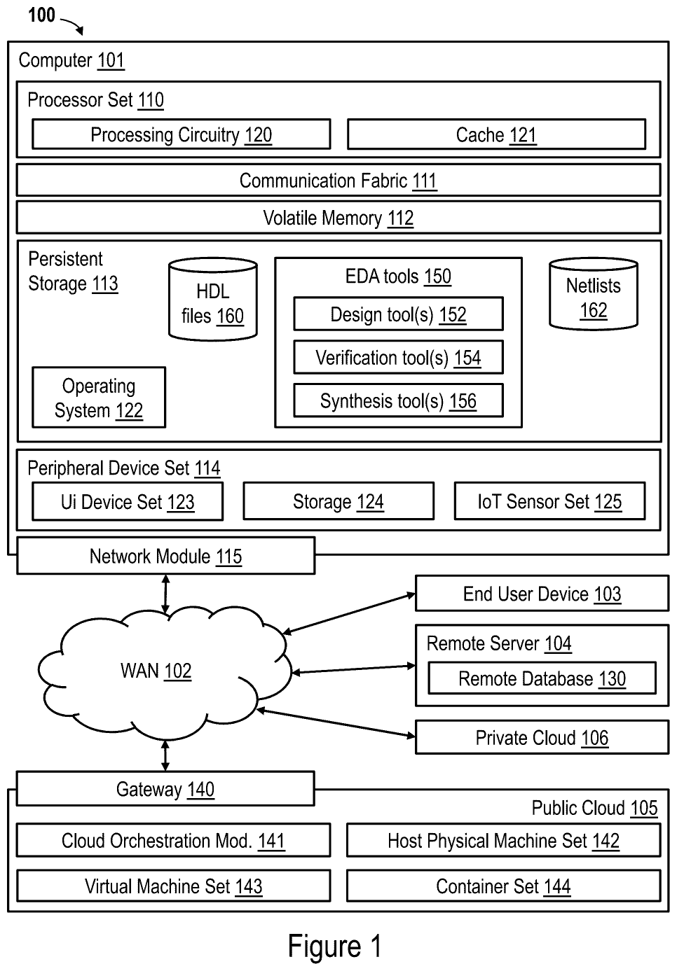

With reference now to FIG. 1, computing environment 100 contains an example of an environment for the execution of at least some of the computer code, such as electronic design automation (EDA) tools 150, involved in performing the inventive methods. In addition, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and other code and data), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one or more computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be implemented in EDA tools 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet-of-Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the Internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Those of ordinary skill in the art will appreciate that the architecture and components of a data processing environment can vary between embodiments. Accordingly, the exemplary computing environment 100 given in FIG. 1 is not meant to imply architectural limitations with respect to the claimed invention.

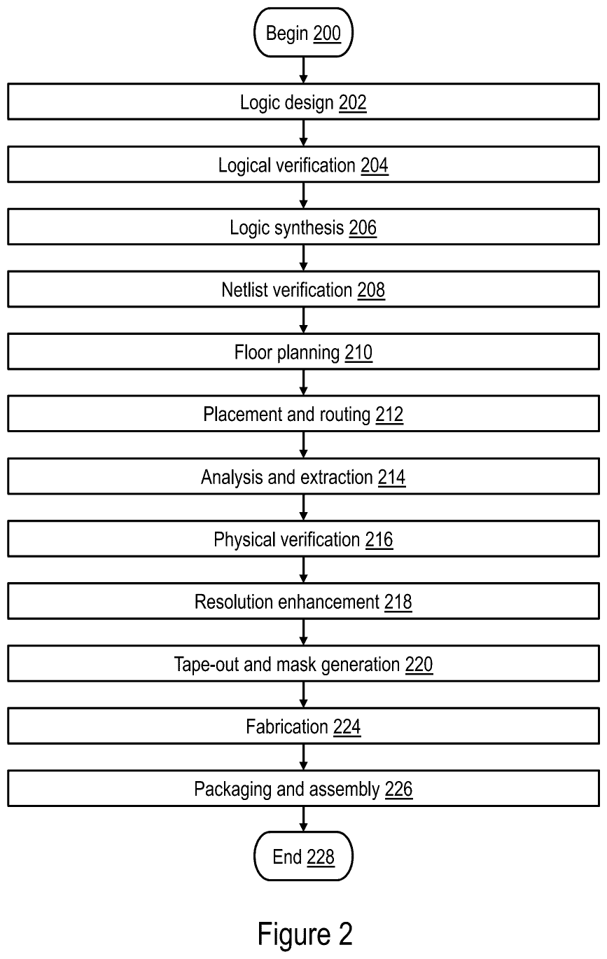

Referring now to FIG. 2, there is depicted a high-level logical flowchart of an integrated circuit design, verification, and fabrication process in accordance with one or more embodiments. The depicted process may be performed, in part, through the use of EDA tools 150, which may include, for example, design tool(s) 152, verification tool(s) 154, and synthesis tool(s) 156. Those skilled in the art will appreciate that many of the steps of the depicted process can be performed contemporaneously and/or in a different order than illustrated, and further, may be performed iteratively. It will also be appreciated that for large-scale designs, it is typical for the overall design to be decomposed into multiple smaller units or entities, for which many of the illustrated steps can be separately performed. In the industry, it is also common for multiple parties to separately perform at least some of the illustrated steps and combine the separate work of the multiple parties through inter-party licensing of intellectual property (IP) blocks and/or contract manufacturing.

The process of FIG. 2 begins at block 200 and then proceeds to bock 202, which illustrates a logic design step 202. In step 202, human and/or automated (e.g., artificial intelligence (AI)) circuit designer(s) may specify an initial design for an integrated circuit using one or more design tool(s) 152. The specification for the integrated circuit may be expressed, for example, within hardware description language (HDL) files 160 utilizing a HDL such as Very High Speed Integrated Circuit Hardware Description Language (VHDL), Verilog, SystemVerilog, SystemC, MyHDL or OpenVera. Those skilled in the art will appreciate that EDA tools 150 may transform the HDL description into one or more lower level design description such as a logic-level RTL description, a gate-level description, a layout-level description, or a mask-level description. Each succeeding lower level of design representation provides more specific details for a particular integrated circuit implementation of the design. During logic design step 202, the design can be decomposed into different entities or units to facilitate parallelization of the design effort and modular processing at subsequent design steps.

After a specification of the logical design is developed at logic design step 202, one or more verification tool(s) 154 are executed to verify the logical correctness of the logic design at logical verification step 204. The verification tool(s) 154 may include, for example, simulators, testbench generators, static HDL checkers, and formal verification tools. Synthesis tool(s) 156 can additionally be executed to transform the logic design represented in HDL files 160 into a netlist 162 in a logic synthesis step 206.

In a typical implementation, a netlist is a directed graph including a plurality of nodes representing “gates” and a plurality of edges representing “wires” (or “nets” or “signals”) between the gates. Gates have associated functions, such as constants, primary inputs, combinational logic (e.g., AND, OR, etc.) and sequential elements (e.g., latches or registers). Hereafter, all sequential elements are referred to as “registers” for brevity. Certain gates are labeled as “primary outputs” of the netlist, which along with primary inputs represent interconnections to other logic components. Logic synthesis step 206 generally must preserve the behavior of primary outputs relative to primary inputs.

Generally, a netlist 162 can support arbitrary gate types with an arbitrary number of input and output pins. However, in some exemplary embodiments, netlist 162 is an AND/Inverter graph in which combinational gates are implemented with simple two-input AND gates, and inversions are implicit attributes of edges. In some cases, different netlist formats are utilized in different steps or stages of the integrated circuit design process. For example, one netlist format allowing physical synthesis-related attributes can be used in logic synthesis step 206, and a different simpler netlist format can be used in the netlist verification step 208 (discussed below). Typically, each different netlist format supports a respective fixed set of gate types. Typically in a design-compilation flow for synthesis or for verification, netlists begin with higher-level gates (e.g., vectored multiplexors and adders). Subsequently, during compilation/model-build flow, the netlist gates are gradually decomposed into smaller, simpler gates, allowing fine-grained optimizations.

Following step logic synthesis step 206, EDA tools 150 can be executed to perform a netlist verification step 208. In netlist verification, EDA tools 150 verify compliance of the netlist for correspondence to the design specified by the HDL files 160 and for compliance with any timing constraints of the design.

EDA tools 150 can then be executed to develop an implementation of the design as a physical integrated circuit. The development of the integrated circuit can begin with a floor planning step 210 in which a basic floor plan for the units and routing for the integrated circuit is constructed. Developing on the high-level physical layout provided by the floor plan, a more detailed physical layout is developed in placement and routing step 212. In step 212, standard cells, individual circuit components (e.g., transistors and capacitors), and routing are physically placed within the integrated circuit floorplan.

EDA tools 150 can additionally Be executed to validate circuit function in an analysis and extraction step 214. In physical verification step 216, EDA tools 150 also verify satisfaction of manufacturing constraints, such as design rule check (DRC) constraints, power constraints, lithography constraints, etc., and further check that the integrated circuit conforms to the HDL design specification. EDA tools 150 further improve the geometry of the physical layout for purpose of manufacturing in a resolution enhancement step 218. Based on the final geometry determined at step 218, EDA tools 150 can generate, in tape-out and mask generation step 220, data sets detailing the design for lithographic masks utilized to fabricate the integrated circuit.

Following tape-out and mask generation step 220, lithographic masks can be utilized to fabricate integrated circuit chips in fabrication step 224. These integrated circuit chips can then be packaged and assembled on circuit cards and/or circuit boards, as depicted in packaging and assembly step 226. Thereafter, the process of FIG. 2 ends at block 228.

The present application presents multiple contributions to the art that individually and/or collectively improve the coverage verification and bug-closure achievable via SFV while reducing consumption of computational resources. These contributions include:
1. Prioritized dynamic rarity-guided simulation, which can include: (a) annotating state partitions with respect to function and affinity, and adjusting priorities accordingly; (b) discounting low-impact partitions near saturation; (c) accelerating partition-discounting via tailoring search to push partitions to saturation.
2. Improved coverage of random simulation via dynamic bias learning and adjustment.
3. Improved BMC coverage on multi-property testbenches, for example, by (a) partitioning properties by fanin-logic affinity; (b) re-partitioning using a subset of fanin-logic identified by localization as appearing sufficient to prevent spurious BMC property failures; (c) dynamically re-partitioning based upon BMC runtime; and (d) adjusting partitions as localization refinements occur.
4. Improved BMC coverage by selecting multiple simulated states as starting states versus a single state. To avoid the historic BMC scalability degradation due to starting BMC from multiple initial states, localization fanin-subset information is utilized to discount irrelevant registers and to select among rare states that differ only by a configurably small number of registers in the important localized fanin-subset.
5. SFV memout avoidance and tailored simulation, for example, by (a) dynamic memory tracking to predict and prevent a memout during BMC, while employing deeper BMC and wider bit-parallel simulation to compensate for coverage loss; (b) tailoring bit-parallel simulation width narrower as search depth grows to conserve simulation memory; (c) dynamically configuring simulation deeper when BMC succeeds to search deeper; and (d) increasing BMC resource and depth if simulation hits a rare scenario (secondary properties referred to herein as “lighthouses”) at a certain depth.
6. Improving coverage in an adaptive SFV framework by varying parameters and search strategies over time, for example, by adjusting parameters such as when different types of lighthouses are introduced and prioritized (checked vs. ignored), which rarity state-partitions are focused on versus discounted, and when random bias learning and BMC partitioning and multiple BMC initial states are employed.

The following discussion assumes that the design being verified, along with its properties and input constraints, is represented as a netlist, such as a netlist 162. A netlist comprises a directed graph with nodes representing “gates,” and edges representing “wires” (or “nets” or “signals”) between those gates. Gates have associated functions, such as constants, random inputs, combinational logic such as AND gates, and sequential elements (e.g., registers). Registers have initial values defining their initial behavior at time t=0; the behavior of a register at a subsequent timestep (i.e., time=i+1) is defined by the values of the register's next-state functions at the previous timestep (i.e., time=i). A sequence of values to netlist gates is called a trace. The values of all sequential elements at a certain timestep of a trace is called a state. An initial state is a state reachable at time=0. Certain gates are labeled as properties, where the verification objective is to compute a trace showing the property gates asserting to Boolean “1” (sometimes called a “property hit”) or to prove that no such trace exists (sometimes called an “unreachability proof”). Multiple different types of properties may be associated with a netlist. These include “correctness properties” which, if hit, represent a design bug (and thus are expected to be proven unreachable unless a design bug exists) and/or “coverage properties” representing scenarios of interest with respect to design behavior which are expected to be hit during verification given enough verification resources. In addition to user-specified properties, secondary properties referred to as “lighthouses” are sometimes generated by a semi-formal verification engine. A variety of types of lighthouses have been proposed, for example, unhit or rarely hit partitioned state values, gates valuations that were never yet simulated, and pairs of gates that were never yet simulated as having different values.

Simulation is a widely used to explore netlist behavior and expose bugs by evaluating the netlist relative to one sequence of input valuations and states at a time. “Verification coverage” models are often used to estimate how effective simulation has been at exposing interesting scenarios, creating “coverage properties” to define those scenarios of interest. Bit-parallel simulation explores multiple sequences concurrently, for example, using each bit of a 64-bit machine word to represent a different simulation sequence. Formal verification (FV) algorithms often operate through reasoning about the netlist using symbolic algorithms, instead of explicit state reasoning employed in simulation. Through use of symbolic algorithms, FV can often cover significantly more traces than feasible using explicit analysis alone. FV can also determine when all design behaviors and states have been explored and generate a correctness proof if no bug is identified in that process. Semi-formal verification (SFV) often operates by leveraging resource-constrained symbolic algorithms and simulation, starting each search Iteration from an interesting state previously reached using a combination of simulation and symbolic algorithms.

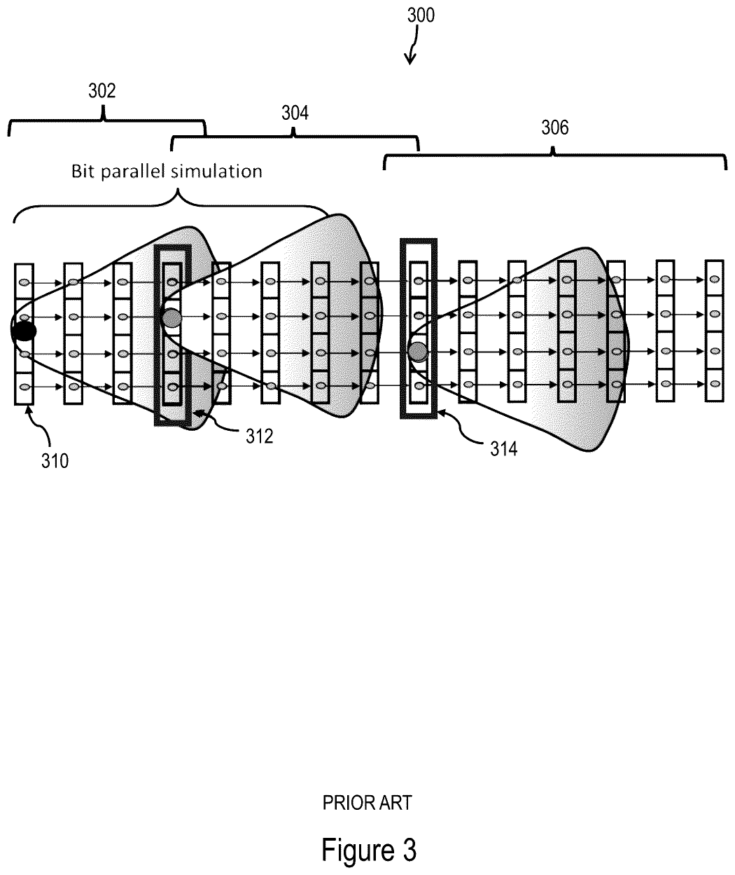

With reference now to FIG. 3, there is illustrated a graphical representation of a semi-formal verification (SFV) process 300 in accordance with the prior art. The illustrated SFV process can additionally be described by the following SFV pseudocode:
1. TRIAL: While (!solved && trial<max_trials) {
2. iteration=1
3. set registers to the netlist's initial states
4. ITERATION: while (!solved && iteration<=max_iterations) {
5. BMC: perform symbolic analysis to try to falsify properties and hit lighthouses for a bmc-time-limit, and optionally, a bmc-depth-limit
6. SIM: perform simulation to try to falsify properties and hit lighthouses for sim-time-limit and sim-depth-limit
7. //Update coverage information and compute rare states for next iteration
8. for each simulated sim_state: {
9. rarity[sim_state]=0
10. for each register partition R: {
11. partition_state=sim_state projected down to registers in R
12. update R[partition_state]++// #of times partition sub-state was simulated
13. rarity[sim_state] +=1/R[partition_state]²// update rarity score of//entire sim_state
14. }
15. }
16. select set of states S with highest rarity[], optionally taking into account states which hit lighthouses; set registers to states S for next iteration
17. iteration++
18. }//end ITERATION
19. trial++
20. }//end TRIAL

This process orchestrates SFV by Trials and by Iterations within each Trial, as indicated by the nested loops found lines 1 and 20 and lines 4 and 18 of the SFV pseudocode. As depicted at reference numeral 302, each Trial begins at Iteration 1, starting from the designated initial states 303 of the netlist. Iteration 2 306 and following iterations (e.g., Iteration 308) begin from a set of heuristically selected interesting states witnessed during prior search. For example, Iteration 2 304 begins from states 312 encountered in Iteration 1 302, and Iteration 3 306 begins at states 314 encountered during Iteration 2 304. These interesting states can be selected using various criteria, for example, whether or not the states hit lighthouses and/or have high rarity values. Effectively, each Iteration concatenates timesteps to a trace starting from the initial states at Iteration 1 of a Trial. When a property is falsified in an Iteration, a counterexample trace exemplifying the bug can be computed by merely concatenating the trace from the current iteration to the one seeding that iteration. Because bit-parallel simulation is often used, instead of selecting a single rarest state, for example, at line 16 of the SFV pseudocode, a set of states (typically one per simulated machine word) is selected for the next iteration. BMC has historically typically been limited to starting from the single most rare state in order to avoid BMC performance degradation when starting from multiple states.

In the SFV process, it is typical to perform multiple Iterations per Trial because symbolic search requires exponentially growing resources with search depth. Intuitively, resource utilization grows exponentially with search depth because the set of states reachable at increasing depth grows exponentially with depth (an additional 2^{v} states are reachable at each successive timestep, where v is the number of random input values of the netlist). Thus, BMC becomes prohibitively slow after a certain netlist-dependent and property-dependent depth. By seeding later Iterations into deeper states, the astronomical coverage of symbolic search is leveraged from states too deep to be reached using symbolic methods from initial states alone. While simulation is not similarly scalability-challenged, it is advantageous to guide simulation to prevent simulation from wasting processing and memory resources exploring uninteresting states that have already been explored. A simple motivating example is a netlist with a reset input: the probability of exploring a trace of length K without resetting the netlist (entailing redundant analysis) is 2^{-K}. The state rarity score computed at line 13 of the SFV pseudocode is an estimate of how often a state was previously explored, allowing later exploration to search less explored states and netlist behaviors.

As presented in SFV pseudocode at lines 7 to 15, state rarity can be computed by partitioning the netlist into smaller groups of registers and then counting the number of times each sub-state of each register partition was simulated. If a netlist has L registers, the total number of possible netlist states is 2^{L}. Even for modestly-sized L, simulating 2^{L} states is not possible even with the largest computing grids and hardware accelerators. Instead, the overall netlist is partitioned into components, e.g., of size N=4, 8, 16, or 32 registers. As indicated at lines 10 to 14 of the SFV pseudocode, simulated sub-states of size N are recorded using L/N counters (each having 2^{N} sub-states), which count the number of times each sub-state of size N was simulated.

This approach allows rarity-guided simulation to scale to very large netlists. Nonetheless, this prior art solution has several challenges when applied to large netlists. For example, the size of L/N can entail many thousands of partitions, and computation of state rarity using the sum of inverse-squared of each partitioned sub-state's simulation count is slower than simulation itself, slowing down the overall SFV engine and limiting coverage. In addition, this prior art approach does not differentiate the rarity contribution of different types of register partitions, allowing less relevant partitions to obscure the importance of more relevant partitions.

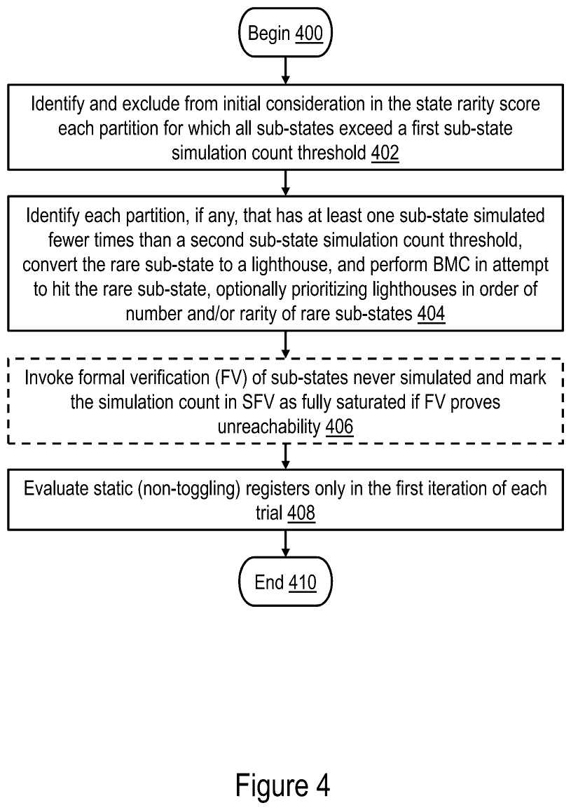

In accordance with one or more embodiments, the prior art SFV process depicted in FIG. 3 and detailed in the above SFV pseudocode can be augmented and refined in a verification tool 154 in order to accelerate SFV and to reduce SFV resource consumption (e.g., of processing circuitry 120 and volatile memory 112 of computer 101). Various of these improvements embodied in verification tool 154 are described below in detail with reference to FIGS. 4-11. Those skilled in the art will appreciate that these improvements can be implemented singly or in combination with other(s) of the disclosed improvements.

Referring now to FIG. 4, there is depicted a high-level logical flowchart of an exemplary process for prioritizing state rarity during SFV in accordance with one or more embodiments.

As noted above, in the SFV pseudocode set forth above, line 13 computes the rarity of a netlist state as the sum of the inverse-squared of each partitioned sub-state's simulation count. This sum is heavily biased by small simulation counts, that is, by partitioned sub-states that were never or rarely simulated. The contribution of a partition to the sum becomes negligible as its simulation count grows. The process of FIG. 4 leverages this fact in multiple ways.

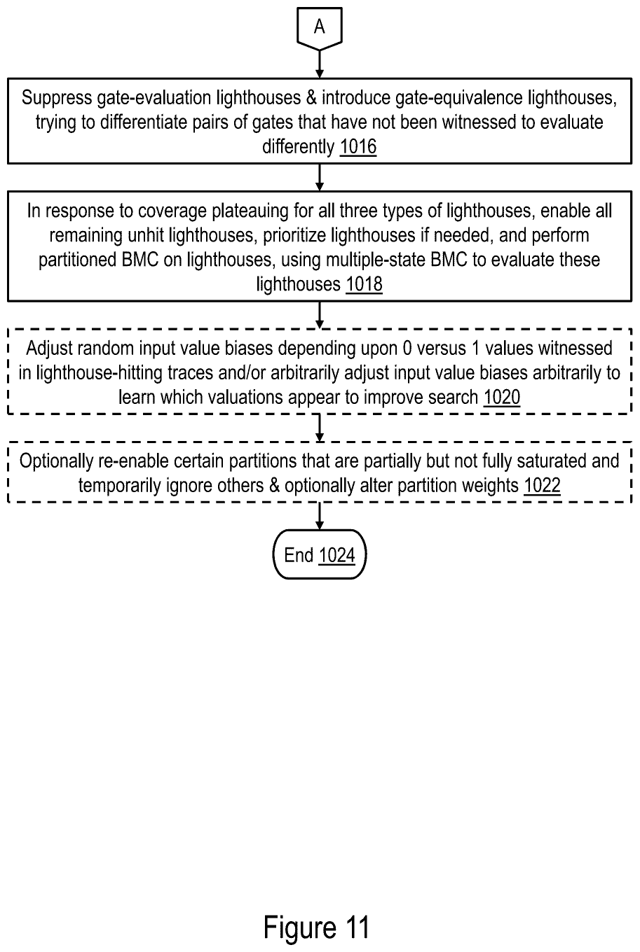

The process of FIG. 4 begins at block 400 and then proceeds to block 402, which illustrates verification tool 154, when performing a SFV process generally of the form of the above SFV pseudocode, identifying and temporarily excluding from inclusion in the computation of the state rarity score each partition having all of its 2^{K} sub-states simulated more times than a configurable first sub-state simulation count threshold. By skipping these partitions nearing saturation (whose temporarily excluded states would not contribute much to the netlist state rarity value, if included), verification tool 154 can gradually accelerate SFV processing, increasing its coverage and efficiency. It should be noted, however, that verification tool 154 can optionally re-enable consideration of these temporarily excluded partitions later in the SFV process, as described below with reference to FIGS. 10-11.

The present application appreciates that some partitions will have many or most of their 2^{K} sub-states simulated many times and a few rare sub-states with a low or even zero simulation count; these rare sub-states prevent saturation. As depicted at block 404, verification tool 154 preferably identifies each partition, if any, having at least one sub-state simulated fewer times than a second sub-state simulation count threshold. At block 404, verification tool 154 converts the rare sub-states identified by reference to the second sub-state simulation threshold into lighthouses and performs BMC to attempt to hit them. In the BMC processing, verification tool 154 can optionally prioritize these lighthouses according to the number of the rare sub-states per partition (e.g., how few sub-states in a partition prevent the partition from being saturated) and/or the rarity of the rare sub-states. For example, if a partition has only a single sub-state preventing its saturation, verification tool 154 can assign the corresponding lighthouse a higher priority in the BMC processing than those in a partition having two rare sub-states preventing saturation. Similarly, verification tool 154 can assign a first lighthouse a higher priority in BMC processing if the corresponding sub-state is more rare than another sub-state corresponding to a second lighthouse.

As shown at block 406, for sub-states that were never previously simulated, verification tool 154 can optionally, in a separate process, attempt to prove those sub-states are unreachable using FV. If a proof of unreachability is obtained via FV, verification tool 154 preferably permanently discounts those unreachable sub-states in SFV processing, e.g. by marking their simulation count as fully saturated.

Block 408 additionally illustrates that verification tool 154 preferably evaluates non-toggling registers (i.e., registers that statically hold their initial values) can be evaluated only in the first iteration of each trial. Verification tool 154 preferably proves unreachability of unused sub-states of non-toggling registers, for example, utilizing a combinational check over initial values. Following block 408, the process of FIG. 4 ends at block 410.

Based on the steps depicted in FIG. 4, the set of partitions for which verification tool 154 records simulation history and rare state scores gradually shrinks the longer the SFV process runs, accelerating the search and allowing the SFV process to focus upon the rarest behaviors within which unexposed bugs may remain.

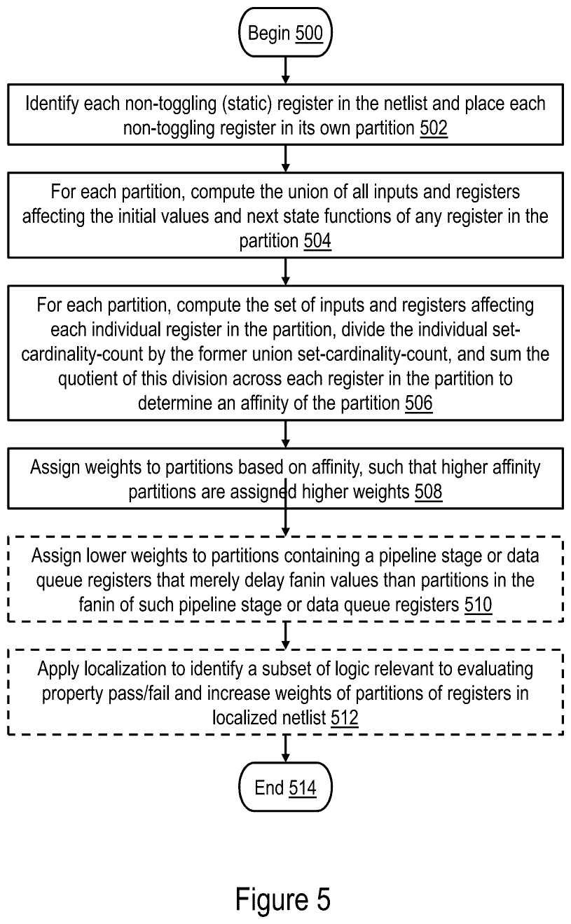

In the prior art SFV processing discussed above, the state rarity computation assigns all partitions an equal weight. The present application recognizes that assigning all partitions the same weight tends to be suboptimal, allowing less relevant subcircuits to obscure high-importance subcircuits. As discussed below with reference to FIG. 5, verification tool 154 preferably assigns a respective partition weight to each partition and multiplies that partition weight by the rarity contribution of the associated partition, such that a subset of partitions influence the state rarity score more heavily than other partitions. As noted below with reference to FIGS. 10-11, verification tool 154 can adjust these partition weights over time, allowing dynamic adjustment of search strategy.

With reference now to FIG. 5, there is illustrated a high-level logical flowchart of an exemplary process for prioritizing partitions during SFV in accordance with one or more embodiments. The process of FIG. 5 begins at block 500 and then proceeds to block 502, which illustrates verification tool 154 identifying each non-toggling (static) register in the netlist and placing non-toggling registers in their own partitions. For example, in one implementation, verification tool 154 places each non-toggling register in its own respective partition.

Verification tool 154 then assigns weights to partitions based on affinity, as depicted at block 504 to 508. At block 504, verification tool 154 computes the union of all inputs and registers affecting the initial values and next-state functions of any register in each partition to obtain a union set-cardinality-count. Verification tool 154 additionally computes the set of inputs and registers affecting each individual register in the partition to obtain an individual set-cardinality-count (block 506). At block 506, verification tool 154 additionally divides this individual set-cardinality-count by the union set-cardinality-count and sums the quotients of this division across each register in the partition to obtain a value representing the affinity of the partition. Verification tool 154 then assigns a respective weight to each partition based on affinity, such that higher-affinity partitions are assigned higher weights and lower-affinity partitions are assigned lower weights (block 508). This assignment of weights to partitions to vary the contributions of partitions to the rarity score improves SFV processing because higher-affinity partition registers are more interdependent, and searching all of their partition sub-states tends to be more relevant to overall netlist behavior than searching sub-states of less interdependent, more arbitrary groups of registers.

Verification tool 154 may optionally adjust the affinity-based weights assigned at block 504-508, as shown at blocks 510 and 512. For example, at block 510, verification tool 154 may downwardly adjust the weights of partitions containing pipeline stages or data queue registers that merely delay fanin values such that these delay partitions have a lower weight than partitions in their fanin. One reason for this adjustment is that registers in the delay partitions have less causality and are restricted to evaluate as they do by their fanin logic. As a result, data-routing registers topologically closer to primary inputs are given higher priority because they have more influence in design operation than registers in their fanout.

Localization is a useful netlist transformation that reduces the amount of logic in the fanin of a property gate by cutpointing various gates, that is, by replacing those gates by random inputs. Because inputs can simulate the behavior of any other gate, localization can cause spurious property failures. When spurious failures are encountered, the localized netlist is “refined” by restoring cutpoints with their original gates and inserting new cutpoints further into fanin logic beyond the refined gates. BMC of the localized netlist is often used to quickly incrementally refine the abstraction to a sufficient logic subset free of spurious failures.

At block 512, verification tool 154 optionally applies localization to identify a subset of logic relevant to evaluating property pass/fail. As localization information becomes available, verification tool 154 preferably increases partition weights of partitions containing registers appearing within the localized netlist. Following block 512, the process of FIG. 5 ends at block 514.

During simulation, inputs are, by default, randomly assigned Boolean “0” and “1” values. It is possible to selectively bias certain inputs to cause the distribution of “0” and “1” input values to diverge from 50%. Input biases significantly affect simulation coverage within each iteration, including the impact of sub-state rarity to select interesting states for subsequent iterations. For example, if a netlist has an input that acts as a reset, flush, or interrupt asserted in 50% of simulation timesteps, the netlist is likely to be frequently simulated in its reset or interrupt-handling state, preventing simulation from reaching deeper states. However, exposing certain bugs may require such inputs to occasionally be asserted, meaning that SFV, to be successful, cannot completely disable such inputs. In accordance with one aspect of the disclosed SFV process, verification tool 154 can dynamically adjust biases across iterations and trials, improving simulation coverage and reaching deeper states.

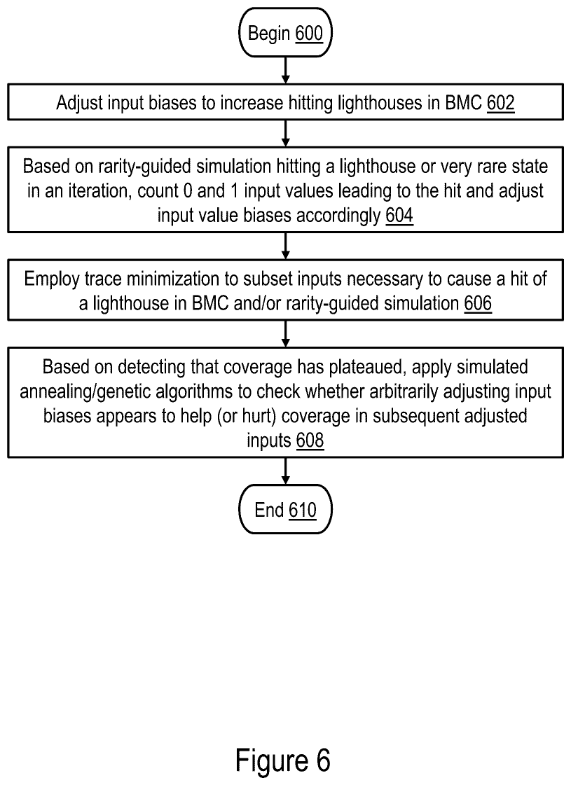

Referring now to FIG. 6, there is depicted a high-level logical flowchart of an exemplary process for dynamically adjusting input biases during SFV in accordance with one or more embodiments. At block 602, verification tool 154 adjusts input biases to increase hits for lighthouses. In at least one embodiment, to adjust the input biases, verification tool 154 extracts a minimal activity trace from BMC and analyzes the minimal activity trace to count Boolean “0” and “1” input values for hits of lighthouses. Verification tool 154 can then adjust the input biases to increase the proportion of “0” and/or “1” input values to increase hits on lighthouses.

Block 604 illustrates that verification tool 154 can additionally adjust input biases based on the results of rarity-guided simulation. For example, when rarity-guided simulation hits a lighthouse or very-rare state in an iteration, verification tool 154 can count the number of “0” and “1” input values leading to that hit and can adjust input value biases accordingly in order to promote hits on additional lighthouses or exploration of very rare states.

As further illustrated at block 606, verification tool 154 can employ Trace minimization to subset which inputs are deemed “necessary” to cause a hit of a lighthouse in BMC and/or rarity-guided simulation. To perform trace minimization, verification tool 154 employs a Boolean satisfiability-like justification process starting at a hit lighthouse gate or rare partition register, minimally marking fanin logic over time as necessary to justify the trace value of interest. For example, if hit occurs on a lighthouse that is an AND gate that evaluates to “1,” all inputs to the AND gate will be justified backward through fanin logic with value “1.” Similarly, if a lighthouse on which a hit occurs is an OR gate evaluating to 1, any single input to the OR gate which evaluates to “1” will be justified backward with value “1.”

Block 608 additionally depicts that verification tool 154 can also adjust input value biases based on simulated annealing/genetic algorithms. For example, based on detecting that coverage has plateaued, verification tool 154 can apply simulated annealing/genetic algorithms to check whether arbitrarily adjusting the biases of input biases appears to help or hurt coverage in subsequent iterations. The set of inputs for which the input value biases are adjusted can be prioritized as those most often appearing in BMC lighthouse hits (regardless of value) and/or in accordance with user-specified hints. In response to witnessing that adjusted biases succeed in hitting lighthouses or very rare states, the adjusted biases are retained for future trials and iterations; if not, the adjustments are discarded in future trials and iterations.

By dynamically varying input biases across trials and iterations in accordance with the method of FIG. 6, verification tool 154 can obtain improved cumulative coverage as compared to static input value biases.

Localization is a known technique to identify the subset of fanin logic that is sufficient to prove or disprove a property. In localization, fanin gates are replaced by cutpoints (random inputs), which might cause spurious property failures. As spurious failures are encountered, certain cutpoints are “refined” by restoring their original gates; cutpoints may then be placed further into the fanin logic beyond the refined gates. BMC is commonly used to refine localization because BMC is often very scalable for shallow unfolding depth. Localization can make BMC even more scalable because less logic is unfolded and analyzed by a Boolean satisfiability (SAT) solver. Refinements can also be made incrementally by adding unfolded logic for the refined gates to the in-memory SAT solver without the cold-start penalty concomitant with starting verification anew after each refinement.

If the netlist has multiple properties, it often is best for FV scalability to partition the properties into high-affinity groups, where each property in a group has a nearly identical set of fanin logic. That partitioning can be performed according to the localized fanin logic subset, once available. Until the fanin logic subset is available, partitioning can be performed according to overall netlist logic. Instead of checking all properties simultaneously using BMC in an iteration, each iteration can either time-slice BMC of high-affinity groups (which can optionally be performed in separate processes) or the set of properties checked using BMC can be limited to selective property groups in each iteration. The latter limitation is particularly useful for lighthouses, which can be very high in number.

As spurious property failures are encountered due to localization, property partitioning can be adjusted after refinement. Additionally, in SFV, the amount of BMC runtime spent checking each property can be assessed (e.g., by adding each property individually to an incremental SAT solver for the current unfolding timestep and tracking solving time for each property). If a significant disparity of runtime is observed for different properties within a group, that group can be subdivided into easier and more difficult properties.

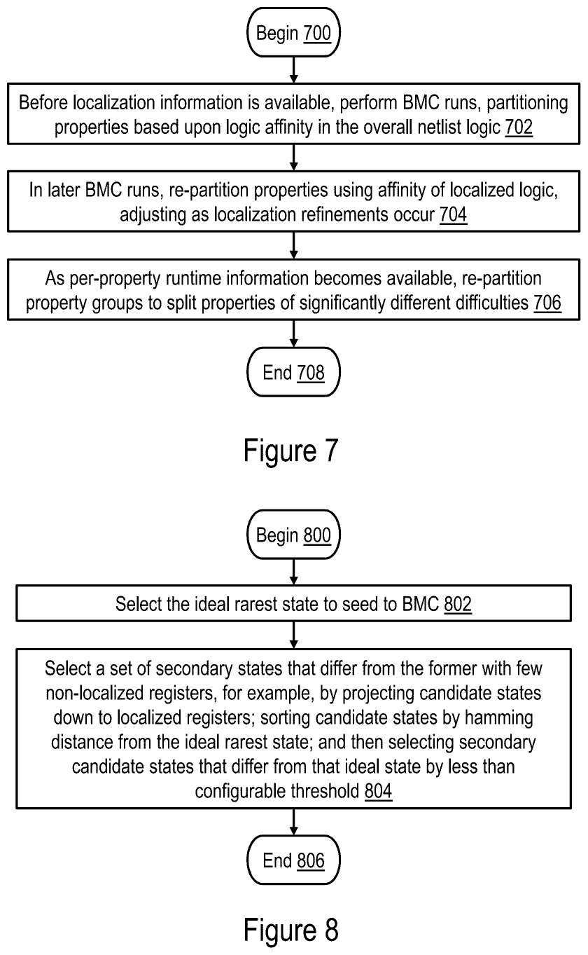

With reference now to FIG. 7, there is illustrated a high-level logical flowchart of an exemplary process for applying localization during SFV in accordance with one or more embodiments. The process of FIG. 7 begins at block 700 and then proceeds to block 702.

Block 702 depicts verification tool 154, during execution of BMC runs before localization information is available, partitioning properties based upon logic affinity in the overall netlist logic. In at least some embodiment, verification tool 154 preferably performs BMC using localization. Initially, verification tool 154 only unfolds property gates and inserts cutpoints on those gate inputs. As spurious failures are encountered, verification tool 154 refines cutpoints and moved them further up the fanin logic cones by unfolding the refined gates. In later BMC runs in which localization information is available, verification tool 154 re-partitions properties based on the affinity of localized logic, adjusted as localization refinements occur (block 704). As per-property runtime information becomes available, verification tool 154 re-partitions property groups to split properties of significantly different difficulties (block 706).

Collectively, the localization techniques depicted in FIG. 7 yield higher quality localized netlists than possible in the prior art. The resulting localized properties can optionally be passed to a FV algorithm (possibly executing on a separate process of processing circuitry 120) trying to prove the correctness of properties. That process is likely to be more scalable and conclusive than possible in the prior art due to a higher quality abstraction that is more immune to difficult-to-compute spurious failures.

The more states from which BMC is performed, the higher the likelihood that one will be near enough to a property failure for BMC to scalably expose that bug. Therefore, starting BMC from a single rare state at each iteration limits total BMC coverage. However, starting BMC from a nondeterministic selection of multiple starting states tends to hurt its scalability and achievable BMC depth (because there is less “constant propagation” of single-state Boolean values to simplify unfolded logic). Thus, conventional solutions rarely perform BMC from multiple starting states to avoid coverage loss through less-scalable BMC.

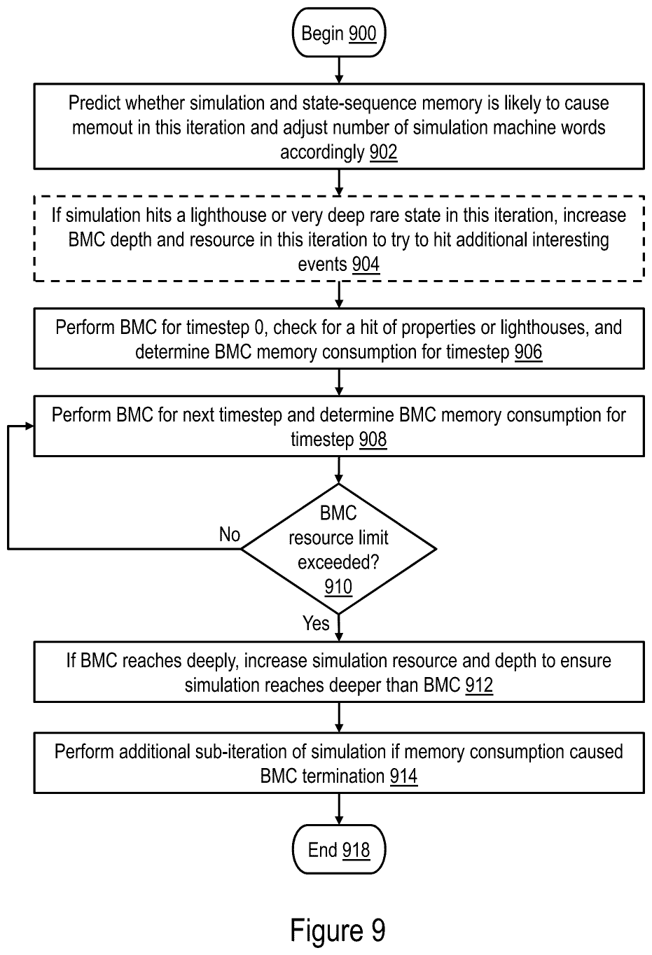

Referring now to FIG. 8, there is depicted a high-level logical flowchart of an exemplary process for performing BMC from multiple starting states with reduced scalability degradation in accordance with one or more embodiments. The process of FIG. 8 begins at block 800 and then proceeds to block 802. Block 802 depicts verification tool 154 first selecting the ideal rarest state to seed BMC. At block 804, verification tool 154 additionally selects a set of secondary states that differ from the ideal state selected at block 802 by only a few non-localized registers. In a preferred embodiment, verification tool 154 performs this selection by projecting candidate states down to localized registers, sorting a larger set of candidate states by Hamming distance from the ideal rarest state, and then selecting, from among the candidate states, a set of secondary states that differ from the ideal state by less than configurable threshold. Verification tool 154 then initiates BMC from the set of secondary states, and the process of FIG. 8 ends at block 806.

Because localized BMC will start from the ideal state anyway and will not unfold non-localized registers for the SAT solver, the process of FIG. 8 causes little BMC scalability degradation and is unlikely to significantly reduce BMC depth and overall coverage. By using a set of seeded BMC states instead of a single initial state, BMC is more likely to hit properties and lighthouses if a secondary seeded state is nearer to that hit (i.e., BMC can hit that property in fewer unfolding timesteps).

BMC and simulation are both memory-intensive. Bit-parallel simulation memory is bounded by the number of netlist gates multiplied by the number of simulated machine words (which are often 50 or fewer 64-bit words) multiplied by the maximum simulation depth in timesteps. Technically, the simulator only needs to allocate one timestep of memory for the simulation process and reuse that memory to simulate each timestep. Nonetheless, for a large netlist, the product of 50 machine words multiplied by the number of netlist gates is still significant. Additionally, the state sequence from initial state to seeded iteration state also is typically stored to allow the iterations'simulation and BMC to be seeded into the state at the end of that trace and to facilitate trace generation if a property failure occurs. These traces are required by design and verification teams to enable debug.

SAT solver memory use is less predictable. While the size of unfolded logic per timestep is predictable, the SAT solver's memory can spike severely at a certain unfolding depth due to learned clauses. Memout is fatal; the SFV process will terminate if it exceeds available memory. However, over-zealous resource bounding (e.g., capping maximum depth or using small time limits) hurts coverage, preventing deeper bugs from being exposed.

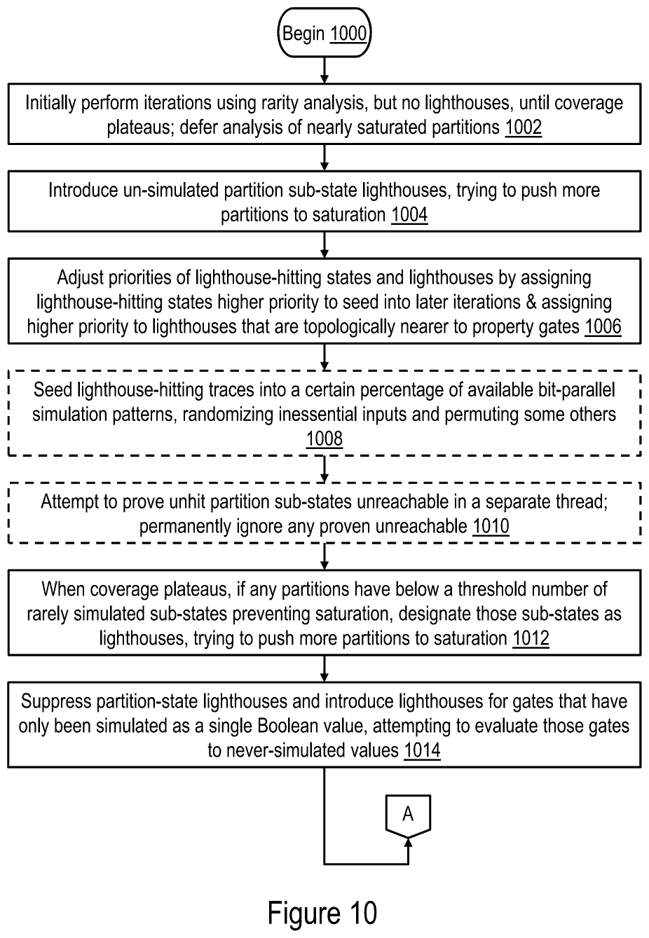

With reference now to FIG. 9, there is illustrated a high-level logical flowchart of a process for avoiding memout during a trial of SFV in accordance with one or more embodiments. The process of FIG. 9 begins at block 900 and then proceeds to block 902, which illustrates verification tool 154 predicting whether simulation and state-sequence memory might cause memout in this iteration based on the number of netlist gates in a netlist 162, simulation and state-sequence length, and the number of simulated machine words. For example, in one embodiment, verification tool 154 predicts a likely memout if (starting state-sequence length+sim-depth-limit)* #gates simulated machine words>sim_mem_threshold. To avoid memout, verification tool 154 preferably reduces the number of simulated machine words as search depth increases. Additionally, within an iteration, BMC is performed for an increasing number of timesteps: first checking if the properties or lighthouses can be hit from the iteration's starting state(s); then in one timestep from the starting state(s); then in two timesteps, etc. This iteration typically continues until a bmc-time-limit for the iteration is exceeded or a bmc-depth-limit (representing the number of timesteps from the BMC starting states) is exceeded. The amount of memory consumed by the SAT solver is monitored for each timestep. If a superlinear increase is detected, verification tool 154 preferably will early terminate these iterations to avoid a subsequent BMC timestep from causing memout.

Following block 902, in block 904 if simulation hits a lighthouse or very deep rare state in an iteration, verification tool 154 can optionally increase BMC depth and resource in that iteration to try to hit additional interesting events. The process then proceeds to block 906, which illustrates verification tool 154 performing BMC for timestep 0, checking whether the iteration's seeded state(s) hit the properties or lighthouses, and extracting the amount of memory the BMC process consumes for this timestep. In block 908, verification tool 154 performs BMC for the next timestep (e.g., timestep 1) and extracts BMC memory consumption for the timestep. In block 910, verification tool 154 determines whether or not a BMC resource limit has been exceeded. For example, at block 910 verification tool 154 may determine whether the difference in memory consumption between the two most-recent BMC timesteps indicates memory consumption has exceeded a configurable BMC_mem_threshold. Similarly, at block 910 verification tool 154 may determine whether or not a bmc-time-limit or bmc-depth-limit has been exceeded. In response to determining at block 910 that a BMC resource limit has been exceeded, verification tool 154 ends BMC, and the process of FIG. 9 proceeds to block 912. Based on a determination that BMC has not exceeded a resource limit, verification tool 154 continues BMC for at least one additional timestep, as indicated by the process of FIG. 9 returning to block 908.

Block 912 depicts verification tool 154 determining if BMC reached deeper than a current sim-depth-limit and, if so, increasing the sim-depth-limit parameter for the next iteration so that simulation reaches deeper than BMC. At block 914, verification tool 154 performs an additional sub-iteration of simulation to compensate for lost coverage, if memory consumption caused BMC termination in block 908. In a preferred embodiment, verification tool 154 performs additional simulation for a depth equal to the last BMC timestep completed at block 908 and then using the iteration's remaining bmc-time-limit to perform BMC from the highest-priority state(s) encountered in that simulation. The process of FIG. 9 thereafter ends at block 918.

A historical problem of SFV is that when coverage saturates, that is, when iterations no longer hit new lighthouses or increment already saturated partitioned sub-state counters, the search becomes highly redundant and unguided. Another problem of conventional SFV is that conventional SFV occasionally resets all state rarity information, forgetting all the coverage that has been achieved. An additional problem of conventional SFV is that the number of lighthouse properties fabricated using traditional methods can be extremely large on large netlists, severely slowing SFV, particularly BMC.

In accordance with one or more embodiments, a verification tool 154 can implement “adaptive search” to address the foregoing problems of conventional SFV, allowing search to focus more efficiently on different criteria over time and to retain the valuable history of prior coverage. This latter capability enables SFV to find intricate bugs in very long SFV runs, which, depending on the resources of the hardware platform, can span days or weeks. As noted below, the adaptive search can implement a variety of techniques, including adjusting weights of rarity partitions, selecting partitions to be ignored in particular iterations, adjusting random biases over time, and adjusting which types of lighthouses are generated and are analyzed in given iterations.

Referring now to FIGS. 10-11, there is depicted a high-level logical flowchart of an exemplary process for adaptive search to improve coverage and scalability of SFV in accordance with one or more embodiments. The process of FIGS. 10-11 begins at block 1000 of FIG. 10 and proceeds to block 1002, which illustrates verification tool 154 initially performing SFV iterations using rarity analysis, but without lighthouses, until coverage plateaus and also deferring analysis of nearly saturated partitions.

At block 1004, verification tool 154 introduces into SFV un-simulated partition sub-state lighthouses in an attempt trying to push more partitions to saturation. In addition, verification tool 154 dynamically adjusts priorities of lighthouses and lighthouse-hitting states by assigning states that hit a lighthouse higher priority to seed into later iterations of SFV and assigning lighthouses that are topologically nearer to property gates higher priorities than others (block 1006). At block 1008, verification tool 154 optionally seeds lighthouse-hitting traces into a certain percentage of available bit-parallel simulation patterns, randomizing non-essential inputs and permuting at least some others. The invocation of bit-parallel simulation at block 1008 enables heavier exploration around lighthouse hits, for example, in cases in which BMC has been terminated to avoid memout. Verification tool 154 can also optionally try to prove unhit partition sub-states are unreachable in a separate thread, permanently ignoring any sub-states proven unreachable (block 1010).

The process proceeds from block 1010 to block 1012, which illustrates verification tool 154 forming additional lighthouses where appropriate when coverage plateaus. For example, in one embodiment, in response to detecting that coverage has plateaued, verification tool 154 determines if any partitions have a very small number of rarely simulated sub-states preventing saturation, and if so, introduces those sub-states as lighthouses in an attempt to push more partitions to saturation. At block 1014, verification tool 154 suppresses partition-state lighthouses and introduces lighthouses for gates that have only been simulated as a single Boolean value, trying to evaluate those gates to never-simulated values. The process then passes to block A to block 1016 of FIG. 11.

At block 1016, verification tool 154 suppresses gate-evaluation lighthouses and introduces gate-equivalence lighthouses in an attempt to differentiate pairs of gates that have not been witnessed to evaluate differently. Based on BMC coverage plateauing with all three types of lighthouses (i.e., partition-state, gate-evaluation, and gate-equivalence), verification tool 154 enables all remaining unhit lighthouses. If there are more lighthouses than can be concurrently evaluated, verification tool 154 prioritizes the lighthouses (e.g., using the foregoing criteria of partition type, topological proximity to inputs and properties, and whether the lighthouse is in localized logic) and enables alternate subsets of lighthouses over time in accordance with the priority. Verification tool 154 additionally performs partitioned BMC on lighthouses, using multiple-state BMC when evaluating lighthouses. As will be appreciated by those skilled in the art, the rotation and prioritization of lighthouses can optionally be applied earlier in SFV, if there are a large number of any one type of lighthouse.

As further illustrated at block 1020, verification tool 154 can optionally adjust random input value biases depending upon the Boolean “0” and “1” values witnessed in lighthouse-hitting traces and/or can arbitrarily adjust input value biases to learn which valuations appear to improve search. Block 1022 additionally depicts that verification tool 154 may optionally re-enable certain partitions that are partially but not fully saturated (e.g., partition state counters are not near 0, though have not fully-saturated to maximal counter values) and temporarily ignore others. Verification tool 1022 may optionally alter partition weights to bias rarity to guide search into different scenarios. Following block 1022, the process of FIGS. 10-11 ends at block 1024. Those skilled in the art will appreciate that various steps of this flow may be optionally suppressed, or introduced in different relative order, without departing from the overall scope of this invention.

As has been described, according to one or more embodiments, a computer-implemented technique of rarity-guided semi-formal verification includes processing circuitry of a data processing system performing semi-formal verification (SFV) of a logic design utilizing a combination of bounded model checking (BMC) and simulation. The processing circuitry guides progress of the simulation in the SFV based on rarity of simulated sub-states of register partitions of the logic design. Guiding the simulation in the SFV includes discounting, in computation of a rarity score, one or more register partitions nearing saturation. Based on the SFV, the processing circuitry identifies a satisfied verification property.

In some embodiments, guiding progress of the simulation in the SFV includes adjusting the relative rarity weights of individual register partitions according to their respective structure and functionality and introducing lighthouses of various types at various iterations of SFV and altering parameters controlling simulation and BMC at various iterations of SFV.

In some embodiments, performing semi-formal verification includes, in performing the bounded model checking, varying prioritization of a plurality of different types of lighthouses. The plurality of different types of lighthouses can include gate-evaluation lighthouses, gate-equivalence lighthouses, and partition sub-state lighthouses.

In some embodiments, performing semi-formal verification includes, in performing the simulation of the logic design, varying biases applied to input values of the logic design based upon the input values witnessed in traces hitting a lighthouse during SFV. In addition, a likelihood of exceeding allocated memory resource during a future simulation is detected, and, based on detecting that likelihood, memory consumption is dynamically reduced by reducing a number of machine words employed in simulation as simulation depth increases.

In some embodiments, performing semi-formal verification includes, in performing the bounded model checking, partitioning properties of the logic design based on a subset of fanin logic identified by localization as sufficient to prevent spurious bounded model checking property failures and re-partitioning properties as localization subsets change at various stages of the SFV.

In some embodiments, performing semi-formal verification includes, in performing BMC, selecting multiple simulated states as starting states for the BMC. The selection of the starting states is made among prioritized rare states that differ from an ideal stating state by fewer than a threshold number of non-localized registers.

In some embodiments, performing semi-formal verification includes, in performing the BMC, avoiding exhaustion of allocated memory resources by detecting a likelihood of a spike in memory usage at a current BMC depth. Based on detecting a likelihood of a spike in memory usage by BMC, memout is prevented by early-terminating BMC and increasing coverage via additional simulation and deeper seeded BMC relative to one or more starting states of the terminated BMC. Based upon not detecting likelihood of a spike in memory usage by BMC, success of simulation in deeply hitting a lighthouse or rare sub-state is detected, and BMC resources for deeper BMC coverage are increased accordingly. Based upon BMC depth exceeding a simulation depth, the simulation depth is dynamically increased.

In some embodiments, formal verification of sub-states and lighthouses not simulated is initiated, and use of sub-states and lighthouses proved unreachable by formal verification is discontinued.

The disclosed techniques can be realized as methods, systems, and/or program products.

While the present invention has been particularly shown as described with reference to one or more preferred embodiments, it will be understood by those skilled in the art that various changes in form and detail may be made therein without departing from the spirit and scope of the invention.

The following definitions are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, system or apparatus that comprises a list of elements is not necessarily limited to only those elements but can include other elements not expressly listed or inherent to such composition, mixture, process, method, article, system or apparatus.

Additionally, the term “exemplary” is used herein to mean “serving as one example, instance or illustration.” Any embodiment or design described herein as “exemplary” is not necessarily to be construed as preferred or advantageous over other embodiments or designs. The terms “at least one” and “one or more” shall be understood to include any integer number greater than or equal to one, and the term “plurality” shall be understood to include any integer number greater than or equal to two. The term “coupled” shall include both indirect connection and a direct connection, unless specified otherwise in a particular case. The terms “about,” “substantially,” “approximately,” and variations thereof, are intended to include the degree of error associated with measurement of the particular quantity based upon the equipment available at the time of filing the application. For example, “about” can include a range of ±10% or ±5%, or ±2% of a given value.

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. For the sake of brevity, conventional techniques related to making and using aspects of the invention(s) may or may not be described in detail herein, and many conventional implementation details are only mentioned briefly or are omitted entirely. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. A computer-implemented method of rarity-guided semi-formal verification, the method comprising:
processing circuitry of a data processing system performing semi-formal verification (SFV) of a logic design utilizing a combination of bounded model checking (BMC) and simulation;
the processing circuitry guiding progress of the simulation in the SFV based on rarity of simulated sub-states of register partitions of the logic design, wherein the guiding includes discounting in computation of a rarity score one or more register partitions nearing saturation;
based on the SFV, the processing circuitry identifying a satisfied verification property.

2. The method of claim 1, wherein guiding progress of the simulation in the SFV includes:
adjusting the relative rarity weights of individual register partitions according to their respective structure and functionality; and
introducing lighthouses of various types at various iterations of SFV and altering parameters controlling simulation and BMC at various iterations of SFV.

3. The method of claim 1, wherein performing semi-formal verification includes:
in performing the bounded model checking, varying prioritization of a plurality of different types of lighthouses, wherein the plurality of different types of lighthouses include gate-evaluation lighthouses, gate-equivalence lighthouses, and partition sub-state lighthouses.

4. The method of claim 1, wherein performing semi-formal verification includes:
in performing the simulation of the logic design, varying biases applied to input values of the logic design based upon the input values witnessed in traces hitting a lighthouse during SFV; and
detecting a likelihood of exceeding allocated memory resource during a future simulation and, based on detecting a likelihood of exceeding the allocated memory resource, dynamically reducing memory consumption by reducing a number of machine words employed in simulation as simulation depth increases.

5. The method of claim 1, wherein performing semi-formal verification includes:
in performing the bounded model checking, partitioning properties of the logic design based on a subset of fanin logic identified by localization as sufficient to prevent spurious bounded model checking property failures and re-partitioning properties as localization subsets change at various stages of the SFV.

6. The method of claim 1, wherein performing semi-formal verification includes:
in performing the bounded model checking (BMC), selecting multiple simulated states as starting states for the BMC, wherein the selection is made among prioritized rare states that differ from an ideal stating state by fewer than a threshold number of non-localized registers.

7. The method of claim 1, wherein performing semi-formal verification includes:
in performing the bounded model checking (BMC), avoiding exhaustion of allocated memory resources by detecting a likelihood of a spike in memory usage at a current BMC depth;
based on detecting a likelihood of a spike in memory usage by BMC, preventing memout by early-terminating BMC and increasing coverage via additional simulation and deeper seeded BMC relative to one or more starting states of the terminated BMC;
based upon not detecting likelihood of a spike in memory usage by BMC, detecting that simulation succeeded in deeply hitting a lighthouse or rare sub-state, and increasing BMC resources for deeper BMC coverage; and
based upon BMC depth exceeding a simulation depth, dynamically increasing the simulation depth.

8. The method of claim 1, further comprising:
the processing circuitry initiating formal verification of sub-states and lighthouses not simulated, and discontinuing use of sub-states and lighthouses proved unreachable by formal verification.

9. A computer program product, comprising:
a storage device; and
program code stored within the storage device and executable by processing circuitry of a data processing system to cause the data processing system to perform:
performing semi-formal verification (SFV) of a logic design utilizing a combination of bounded model checking (BMC) and simulation;
guiding progress of the simulation in the SFV based on rarity of simulated sub-states of register partitions of the logic design, wherein the guiding includes discounting in computation of a rarity score one or more register partitions nearing saturation;
based on the SFV, identifying a satisfied verification property.

10. The program product of claim 9, wherein guiding progress of the simulation in the SFV includes:
adjusting the relative rarity weights of individual register partitions according to their respective structure and functionality; and
introducing lighthouses of various types at various iterations of SFV and altering parameters controlling simulation and BMC at various iterations of SFV.

11. The program product of claim 9, wherein performing semi-formal verification includes:
in performing the bounded model checking, varying prioritization of a plurality of different types of lighthouses, wherein the plurality of different types of lighthouses include gate-evaluation lighthouses, gate-equivalence lighthouses, and partition sub-state lighthouses.

12. The program product of claim 9, wherein performing semi-formal verification includes:
in performing the simulation of the logic design, varying biases applied to input values of the logic design based upon the input values witnessed in traces hitting a lighthouse during SFV; and
detecting a likelihood of exceeding allocated memory resource during a future simulation and, based on detecting a likelihood of exceeding the allocated memory resource, dynamically reducing memory consumption by reducing a number of machine words employed in simulation as simulation depth increases.

13. The program product of claim 9, wherein performing semi-formal verification includes:
in performing the bounded model checking, partitioning properties of the logic design based on a subset of fanin logic identified by localization as sufficient to prevent spurious bounded model checking property failures and re-partitioning properties as localization subsets change at various stages of the SFV.

14. The program product of claim 9, wherein performing semi-formal verification includes:
in performing the bounded model checking (BMC), selecting multiple simulated states as starting states for the BMC, wherein the selection is made among prioritized rare states that differ from an ideal stating state by fewer than a threshold number of non-localized registers.

15. The program product of claim 9, wherein performing semi-formal verification includes:
in performing the bounded model checking (BMC), avoiding exhaustion of allocated memory resources by detecting a likelihood of a spike in memory usage at a current BMC depth;
based on detecting a likelihood of a spike in memory usage by BMC, preventing memout by early-terminating BMC and increasing coverage via additional simulation and deeper seeded BMC relative to one or more starting states of the terminated BMC;
based upon not detecting likelihood of a spike in memory usage by BMC, detecting that simulation succeeded in deeply hitting a lighthouse or rare sub-state, and increasing BMC resources for deeper BMC coverage; and
based upon BMC depth exceeding a simulation depth, dynamically increasing the simulation depth.

16. The program product of claim 9, wherein the program code further causes the processing circuitry to perform:
initiating formal verification of sub-states and lighthouses not simulated, and discontinuing use of sub-states and lighthouses proved unreachable by formal verification.

17. A data processing system, comprising:
a storage device; and
program code stored within the storage device and executable by processing circuitry of a data processing system to cause the data processing system to perform:
performing semi-formal verification (SFV) of a logic design utilizing a combination of bounded model checking (BMC) and simulation;
guiding progress of the simulation in the SFV based on rarity of simulated sub-states of register partitions of the logic design, wherein the guiding includes discounting in computation of a rarity score one or more register partitions nearing saturation;
based on the SFV, identifying a satisfied verification property.

18. The data processing system of claim 17, wherein guiding progress of the simulation in the SFV includes:
adjusting the relative rarity weights of individual register partitions according to their respective structure and functionality; and
introducing lighthouses of various types at various iterations of SFV and altering parameters controlling simulation and BMC at various iterations of SFV.

19. The data processing system of claim 17, wherein performing semi-formal verification includes:
in performing the bounded model checking, varying prioritization of a plurality of different types of lighthouses, wherein the plurality of different types of lighthouses include gate-evaluation lighthouses, gate-equivalence lighthouses, and partition sub-state lighthouses.

20. The data processing system of claim 17, wherein performing semi-formal verification includes:
in performing the simulation of the logic design, varying biases applied to input values of the logic design based upon the input values witnessed in traces hitting a lighthouse during SFV; and
detecting a likelihood of exceeding allocated memory resource during a future simulation and, based on detecting a likelihood of exceeding the allocated memory resource, dynamically reducing memory consumption by reducing a number of machine words employed in simulation as simulation depth increases.
